(19) United States
(12) Patent Application Publication
(10) Pub. No.: US 2018/0097169 A1
(43) Pub. Date: Apr. 5, 2018

(54) RESIN PRODUCT AND METHOD FOR MANUFACTURING A RESIN PRODUCT

(71) Applicant: CANON COMPONENTS, INC., Saitama-ken (JP)

(72) Inventor: Taisuke IWASHITA, Saitama-ken (JP)

(21) Appl. No.: 15/669,222

(22) Filed: Aug. 4, 2017

(30) Foreign Application Priority Data
Oct. 3, 2016 (JP) 2016-195991

(51) Int. Cl. H01L 35/32; H01L 35/34

(52) U.S. Cl. CPC H01L 35/32; H01L 35/34

(57) ABSTRACT

There is provided with a method of manufacturing a resin product. The method includes preparing a resin substrate that is provided with, in a first portion on a surface of the resin substrate, a first patterned layer of a first material. The method also includes forming a second patterned layer of a second material in a second portion on the surface of the resin substrate, by irradiating the second portion with ultraviolet light and then subjecting the second portion to electroless plating.

### BACKGROUND OF THE INVENTION

### Field of the Invention

The present invention relates to a resin product and method for manufacturing a resin product.

### Description of the Related Art

Various devices can be produced by forming multiple types of layers on a substrate. For example, a Seebeck element (a type of thermoelectric element) can be produced by providing metal films made of different materials on a substrate so that they are in contact with each other. An example of such a Seebeck element is described in Japanese Patent Laid-Open No. 2010-2332.

If a fine patterned layer is formed on a substrate, various advantages are brought about. For example, a fine wiring pattern can realize a downsized and high-performance device. Furthermore, when a Seebeck element is produced, a fine wiring pattern makes it easy to increase the number of metal films that are connected on each other in succession, improving an electromotive force.

### SUMMARY OF THE INVENTION

According to an embodiment of the present invention, a method of manufacturing a resin product, comprises: preparing a resin substrate that is provided with, in a first portion on a surface of the resin substrate, a first patterned layer of a first material; and forming a second patterned layer of a second material in a second portion on the surface of the resin substrate, by irradiating the second portion with ultraviolet light and then subjecting the second portion to electroless plating.

According to another embodiment of the present invention, a resin product comprises: a resin substrate; a first patterned layer of a first material that is provided on a surface of the resin substrate; and a second patterned layer of a second material that is provided on the surface of the resin substrate.

Further features of the present invention will become apparent from the following description of exemplary embodiments (with reference to the attached drawings).

### BRIEF DESCRIPTION OF THE DRAWINGS

FIGS. 1A-1C are diagrams illustrating a manufacturing method according to an embodiment.

FIG. 2 is a flowchart of the manufacturing method according to an embodiment.

FIGS. 3A-3B are diagrams illustrating a structure of a resin product according to an embodiment.

FIGS. 4A-4D are diagrams illustrating a manufacturing method according to an embodiment.

FIGS. 5A-5B are diagrams illustrating a structure of a resin product according to an embodiment.

### DESCRIPTION OF THE EMBODIMENTS

Japanese Patent Laid-Open No. 2010-2332 employs photolithography for forming a metal wiring pattern. According to this method, in photolithography, a metal film is formed over the entire surface of a substrate, and then a part thereof is removed. However, with the method described in Japanese Patent Laid-Open No. 2010-2332, it is difficult to provide two types of metal films on a substrate surface. Accordingly, in Japanese Patent Laid-Open No. 2010-2332, a copper layer is attached to one surface of the substrate, a nickel layer is attached to the other surface, and both of the surfaces are independently subjected to patterning. Such a method requires a number of processing steps, and also increases waste products such as waste liquid.

Selective sputtering or vapor deposition using a mask is also possible.
1) However, it is difficult to form a fine patterned layer in a mask with patterned holes that is used in sputtering or vapor deposition, because it is not easy to form a fine pattern in that mask compared to a quartz chrome mask that is used in exposure or the like;
2) Furthermore, the mask is provided with through holes at positions that correspond to a layer forming portion of a substrate. Accordingly, it is not possible to form a so-called island pattern, in which an island is enclosed by the layer forming portion.
3) Furthermore, a material for use in layer formation adheres to the mask as well, and a cost will be incurred for removing the fixed material from the mask. Particularly, if both materials for forming the mask and a layer are inorganic substances, there is the risk that the mask is also damaged when the fixed material is removed.
4) Furthermore, an expensive vacuum apparatus is needed, and it is difficult to form a patterned layer on a large-area substrate.

One embodiment of the present invention provides a method for easily providing layers made of a plurality of different materials on a resin product.

Hereinafter, embodiments to which the present invention is applicable will be described with reference to the drawings. Note that the scope of the present invention is not limited to the embodiments below.

### EMBODIMENT 1

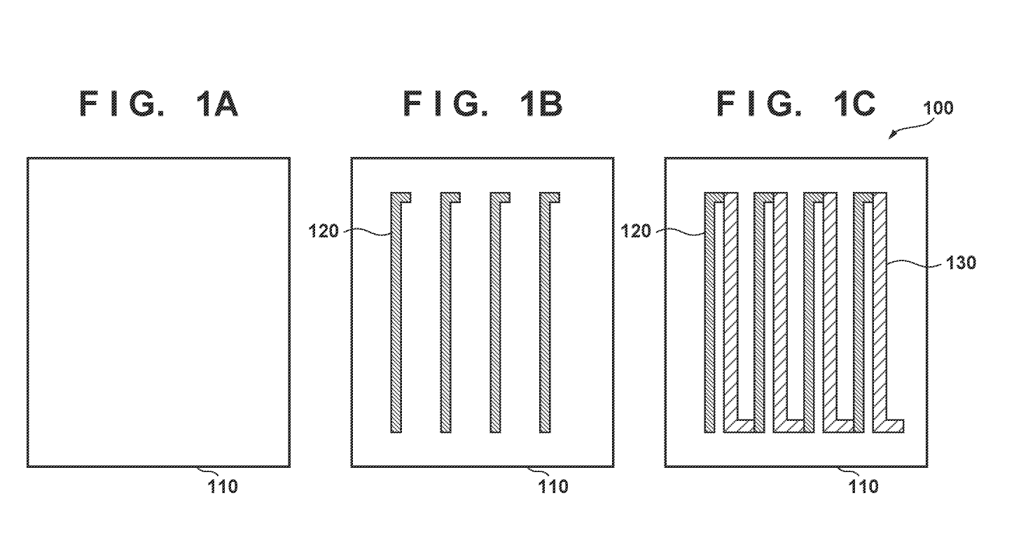

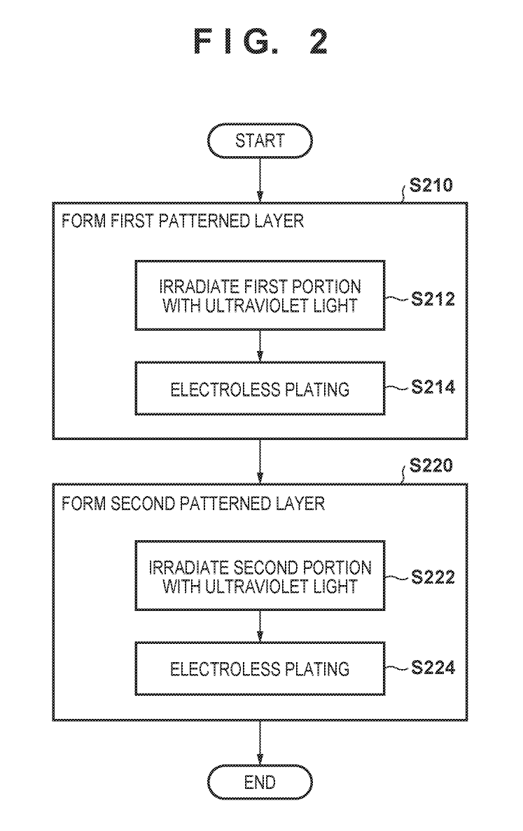

A resin product manufacturing method according to the present embodiment includes a first formation step, and a second formation step. In the first formation step, a first patterned layer of a first material is formed on a surface of a resin substrate. In the second formation step, a second patterned layer of a second material is formed on the surface of the resin substrate on which the first patterned layer has been formed. Thus, a resin product that is provided with the first patterned layer of the first material and the second patterned layer of the second material is produced. Here, the first patterned layer and the second patterned layer are formed on the same surface of the resin substrate. Furthermore, the second patterned layer is formed in the portion on the surface of the resin substrate in which the first patterned layer has not been formed. The following will describe these steps in detail with reference to the schematic views of FIGS. 1A to 1C, and the flowchart of FIG. 2.

In the present embodiment, the first patterned layer and the second patterned layer that are respectively made of the first material and the second material that are different from each other are provided on the surface of the resin substrate. Furthermore, layers that are respectively made of three or more types of materials that are different from each other may also be provided on the surface of the resin substrate, as will be described later. Here, “materials different from each other” means that the materials have compositions that are different from each other. The materials different from each other may include the same component, for example, the same compound or element. For example, in one embodiment, the first material is copper, and the second material is a combination of copper and nickel. Furthermore, in one embodiment, one of materials different from each other contains a component that is not contained in another material, for example, a compound or element that is not contained in another material.

First, a resin substrate 110 of the present embodiment that is shown in FIG. 1A is described, the first patterned layer and the second patterned layer being formed on the resin substrate 110. The material of the resin substrate 110 is not particularly limited, and examples thereof include: a polyolefin resin including a cyclic polyolefin resin such as a cycloolefin polymer; a polyimide resin; a polyvinyl resin such as vinyl chloride; a polyester resin; a polystyrene resin; a polycarbonate resin; and a liquid crystal polymer resin. The resin substrate 110 may be made of a combination of two or more types of resins. Furthermore, the resin substrate 110 may be made of a composite material of a resin material and a material other than resin.

The resin substrate 110 is commercially available and easily accessible. In one embodiment, the shape of the resin substrate 110 is selected so that it is easily subjected to modification by ultraviolet irradiation, which will be described later. For example, a resin substrate 110 that partially has a flat surface may be used. Such flat surfaces can be modified all together at a low production cost using, for example, an ultraviolet lamp, or, in combination therewith, scanning exposure using an ultraviolet laser having a linear irradiation range. Accordingly, the modification by ultraviolet irradiation as described above may employ an ultraviolet lamp solely, or in combination with an ultraviolet laser. Furthermore, modification may also be realized by physically roughening or chemically modifying a resin substrate only using laser beam irradiation. Furthermore, modification may be performed under an atmospheric environment or a liquid environment. The modification method is selected appropriately based on the characteristics of a substrate to be used.

In one specific embodiment, the shape of the resin substrate 110 is flat. In one embodiment, a commercially available film-shaped resin substrate 110 may be used. The thickness of the film-shaped resin substrate 110 is not particularly limited, and may be in a range from 10 μm to 1.0 mm inclusive, for example. On the other hand, the resin substrate 110 is not limited to a flat substrate, and may also be a substrate whose surface is uneven or curved. The property of light of an ultraviolet laser beam travelling straight, or a mask that fits to the shape of the substrate can be used to modify, with ultraviolet light, also a non-flat portion of the substrate in a pattern shape.

### First Formation Step

In the first formation step (step S210), a first patterned layer 120 of a first material is formed in a first portion on a surface of the resin substrate 110. The resin substrate 110 provided with the first patterned layer 120 that is obtained in step S210 is shown in FIG. 1B. The type of the first material is not particularly limited, and a method for forming the first patterned layer 120 is also not particularly limited. The first material may be, for example, a metal material, and examples of the metal material include metal such as copper or nickel, an alloy such as a constantan (copper-nickel), and a metal oxide such as a zinc oxide. Furthermore, the first material may also be a composite semiconductor such as a BiTe. Examples of the method for forming the first patterned layer 120 include a method for selectively forming the first patterned layer 120 using electroless plating. The electroless plating method is advantageous in its simple operation. On the other hand, a conventional patterning method using photolithography and etching, or a conventional method such as one in which sputtering or vapor deposition is performed via a mask may be used, in order to utilize existing equipment.

The following will describe the method for selectively forming the first patterned layer 120 using electroless plating. If electroless plating is used, then the first formation step (step S210) includes a step for selectively modifying the first portion on the surface of the resin substrate 110 so that a plating material is deposited using electroless plating (step S212). Furthermore, the first formation step (step S210) further includes a step for subjecting the resin substrate 110 to electroless plating to form the first patterned layer 120 in the first portion (step S214). The following will describe these steps.

### Modification Step

In step S212, the first portion on the surface of the resin substrate 110 is selectively modified so that an electroless plating layer is deposited. This first portion is a portion in which the first patterned layer 120 on the surface of the resin substrate 110 is deposited. The modification of the first portion is performed by various methods that have been used as a pretreatment for electroless plating on resin. Examples of the modification method include, without being limited to, a photoexcited ashing process, a plasma ashing process, ultraviolet irradiation, an acid treatment with chromic acid or the like, and an alkali treatment with a sodium hydroxide or the like.

For example, in selective modification by ultraviolet irradiation, it is possible to selectively irradiate the first portion with ultraviolet light via, for example, a mask having an ultraviolet light-transmitting portion that corresponds to a plating pattern to be deposited. Furthermore, it is also possible to selectively irradiate the substrate with a laser beam directly without a mask, using the property of light such as an ultraviolet laser beam travelling straight. Furthermore, if an alkali treatment or an acid treatment is used to perform modification, a mask that has an opening corresponding to the shape of the first portion may be formed on the resin substrate 110, and the resin substrate 110 may be dipped in alkali or acid, so that the first portion is selectively modified. The present embodiment employs the modification method by ultraviolet irradiation that can easily achieve selective modification. In other words, the first portion on the surface of the resin substrate 110 is irradiated with ultraviolet light in step S212, and then is subjected to electroless plating, so that the first patterned layer 120 is formed in the first portion.

Specifically, the surface of the resin substrate 110 is modified by being irradiated with ultraviolet light under an atmosphere that includes at least either one of oxygen and ozone, that is, a gas that includes at least either one of oxygen and ozone. In one embodiment, the surface is irradiated with ultraviolet light having a wavelength of not greater than 243 nm. In an atmosphere that includes oxygen, the ultraviolet light having a wavelength of not greater than 243 nm degrades an oxygen molecule in the atmosphere, and ozone is generated. Furthermore, in the course of degradation of the ozone, active oxygen is generated. The active oxygen thus generated reacts to the surface of the resin substrate 110 that was similarly activated by ultraviolet light, and oxidizes the surface of the resin substrate 110, so that a hydrophilic group such as a carboxyl group is formed on the surface of the resin substrate 110. Accordingly, it is conceivable that the surface of the resin substrate 110 is modified so as to easily absorb a catalyst, a catalytic ion, or a binder material that binds the resin substrate 110 with a catalytic ion.

The principle of modification will be described in more detail. The energy of a photon having a specific wavelength can be expressed in the following formula.

E=Nhc/λ (KJ·mol⁻¹)

where N=6.022×10²³ mol⁻¹ (Avogadro's number), h=6.626×10⁻³⁷ KJ·s (Planck's constant), c=2.988×10⁸m·s⁻¹ (speed of light), and λ=wavelength of light (nm).

Here, the binding energy of oxygen molecules is 490.4 KJ·mol⁻¹. By substituting the binding energy in the photon energy formula, the wavelength of light is calculated as about 243 nm. This means that oxygen molecules in the atmosphere absorb ultraviolet light having a wavelength of not greater than 243 nm, and are degraded. With this, ozone O₃ is generated. Furthermore, in the course of degradation of the ozone, active oxygen is generated. If, at this time, ultraviolet light having a wavelength of not greater than 310 nm exists, the ozone is efficiently degraded, resulting in efficient generation of active oxygen. Furthermore, ultraviolet light having a wavelength of 254 nm degrades ozone most efficiently.

O₂+hν(not greater than 243 nm)→O (3P)+O (3P)

O₂+O (3P)→O₃ (ozone)

O₃+hν(not greater than 310 nm)→O₂+O(1D) (active oxygen)

Where O(3P) is a ground state oxygen atom, and O(1D) is an excited oxygen atom (active oxygen).

Specifically, when the surface of the resin substrate 110 is irradiated with ultraviolet light having a wavelength of not greater than 243 nm, then oxygen in the atmosphere is degraded, and ozone is generated. Furthermore, in the course of degradation of the ozone, active oxygen is generated. Furthermore, a bond of molecules that constitute the resin substrate 110 is also dissociated on the surface of the resin substrate 110. At this time, the molecules constituting the resin substrate 110 react to the active oxygen, and the surface of the resin substrate 110 is oxidized, that is, a C—O bond, a C═O bond, a C(═O)—O bond (the backbone of a carboxyl group), and the like are formed on the surface of the resin substrate 110. Such a hydrophilic group increases the chemical adsorption property between the resin substrate 110 and the plating layer. Furthermore, the oxidation of the surface of the resin substrate 110 allows a fine roughened surface to be formed particularly after a pretreatment for plating, thus increasing the physical adsorption property between the resin substrate 110 and the plating layer due to an anchor effect. Furthermore, the modified portion can absorb selectively a catalyst used in electroless plating, a catalytic ion serving as a precursor for a catalyst, or a binder material for binding the resin substrate 110 with the catalytic ion.

Such ultraviolet light can be emitted by an ultraviolet lamp or an ultraviolet LED that continuously emits ultraviolet light. Examples of the ultraviolet lamp include a low-pressure mercury lamp and an excimer lamp. A low-pressure mercury lamp can emit ultraviolet light having wavelengths of 185 nm and 254 nm. Furthermore, examples of an excimer lamp that can be used in the atmosphere will follow for reference. Typically, a Xe₂ excimer lamp is used as the excimer lamp.
Xe₂ excimer lamp: Wavelength of 172 nm
KrBr excimer lamp: Wavelength of 206 nm
KrCl excimer lamp: Wavelength of 222 nm

When the resin substrate 110 is irradiated with ultraviolet light, the irradiation with ultraviolet light is controlled so as to have a desired irradiation amount. The irradiation amount can be controlled by changing the irradiation time. Furthermore, the irradiation amount can also be controlled by changing the output of the ultraviolet lamp, the number of lamps, the irradiation distance, or the like.

In one embodiment, in the modification step, the irradiation amount of ultraviolet light at a wavelength of 185 nm is set to be a range from 400 mJ/cm² to 5000 mJ/cm² inclusive, in view of a plating material being sufficiently deposited in a shorter time period. For example, in one embodiment in which the ultraviolet light at the wavelength of 185 nm has the irradiation intensity of 1.35 mW/cm², the irradiation time of the ultraviolet light is set to be not shorter than 5 minutes in view of achieving sufficient modification. On the other hand, in one embodiment, the irradiation time of ultraviolet light is set to be not longer than 60 minutes in view of increasing the productivity. Hereinafter, the irradiation amount and the irradiation intensity that will be mentioned are values for ultraviolet light having a wavelength of 185 nm, unless otherwise noted.

The plating deposition conditions depend on the type of plating solution, the type of resin, the condition of a reactivation step, the degree of pollution on a resin surface, the density, temperature, pH, and time degradation of plating solution, and a change in output of the ultraviolet lamp, for example. Accordingly, the irradiation amount of light from the ultraviolet lamp should be determined so that a plating material is selectively deposited only in the portion that is irradiated with the ultraviolet light. A purpose of the modification by ultraviolet irradiation is to selectively form, in a modified portion, a chemical absorption group such as a carboxyl group, a hydroxyl group, or the like, and a fine roughened surface for which an anchor effect is expected. The modification method is not limited to the above-described method or conditions as long as this purpose can be achieved.

Furthermore, an ultraviolet laser may also be used as an ultraviolet light source. An ultraviolet lamp or an ultraviolet LED, and the ultraviolet laser may be used together if necessary. For example, the first portion is irradiated with an ultraviolet laser beam, and then the entire resin substrate 110 may be irradiated with light from the ultraviolet lamp or the ultraviolet LED. In this case, the irradiation amounts of light from the ultraviolet laser, and the ultraviolet lamp or the ultraviolet LED are controlled so that a desired portion is modified to the extent that an electroless plating layer is deposited, and the remaining portion is modified to the extent that no electroless plating layer is deposited. This method can be used to form a fine patterned layer, because the use of an ultraviolet laser enables the first portion to be irradiated with ultraviolet light with more accuracy.

### Plating Step

In step S214, electroless plating is performed on the resin substrate 110 so that the first patterned layer 120 is formed in the first portion. Since the first portion is selectively modified in step S212, the first patterned layer 120 can selectively be formed in the first portion of the resin substrate 110 in step S214. Accordingly, in the present embodiment, the resin substrate 110 may also be dipped in electroless plating solution in step S214. In the electroless plating step, the same method as one that has conventionally been used in electroless plating on resin may be used. For example, the electroless plating step may be performed using an electroless plating solution set such as Cu-Ni plating solution set “AISL” of JCU Corporation. In the present embodiment in which the first portion is modified using ultraviolet light, nano-level unevenness in the first portion is caused due to ultraviolet irradiation, and thus it is possible to achieve higher adhesion between the first patterned layer 120 and the resin substrate 110 due to an anchor effect therebetween.

The specific electroless plating method is not particularly limited. Examples of applicable electroless plating include electroless plating using a formalin electroless plating bath, and electroless plating using, as a reducing agent, hypophosphorous acid, which has a slow deposition rate but is easy to deal with. The first material of which the first patterned layer 120 is made is not limited to metal as long as it can be deposited by a catalyst. In one embodiment, an alloy, a compound semiconductor, or a ceramic layer made of a metal oxide is formed. Furthermore, the first patterned layer 120 may also be formed using a high-speed electroless plating method, in order to have a thicker plating film. Further specific examples of electroless plating include electroless nickel plating, electroless copper plating, electroless copper nickel plating, and zinc oxide plating.

In one embodiment, the electroless plating may be performed in the following manner.
1) The resin substrate is dipped in an alkali solution and defatted, so as to have increased hydrophilicity (alkali treatment).
2) The resin substrate is dipped in a solution that contains a binder, such as a cationic polymer, of a resin product and a catalytic ion (conditioner treatment).
3) The resin substrate is dipped in a solution containing a catalytic ion (activator treatment).
4) The resin substrate is dipped in a solution containing a reducing agent to reduce the catalytic ion, so that a catalyst is deposited (accelerator treatment).
5) The resin substrate is dipped in an electroless plating solution so that a plating material is deposited on the deposited catalyst (electroless plating processing).

Electrolytic plating may further be performed on the resin substrate 110 so as to increase the film thickness of the first patterned layer 120. The specific electrolytic plating method is not particularly limited, and may be, for example, nickel plating, copper plating, copper nickel plating, or the like. Furthermore, examples of the material of electrolytic plating include zinc, silver, cadmium, iron, cobalt, chrome, a nickel-chrome alloy, tin, a tin-lead alloy, a tin-silver alloy, a tin-bismuth alloy, a tin-copper alloy, gold, platinum, rhodium, palladium, a palladium-nickel alloy, and zinc oxide. Furthermore, displacement plating using silver or the like may be added if needed. According to the method of the present embodiment, the thickness of the first patterned layer 120 is not greater than 100 pm in one embodiment.

Second Formation Step

In the second formation step (S220), a second patterned layer 130 of a second material is provided in a second portion on the surface of the resin substrate 110. A resin product 100 that is obtained by providing the second patterned layer 130 on the resin substrate 110 in step S220 is shown in FIG. 1C. In the second formation step, the second patterned layer 130 is provided using electroless plating. The second material is not particularly limited as long as it can be formed using electroless plating.

In the second formation step (S220), the second portion of the surface of the resin substrate 110 is irradiated with ultraviolet light, and then is subjected to electroless plating so that the second patterned layer 120 is formed on the second portion. According to the present embodiment, step S220 includes a step for irradiating the second portion on the surface of the resin substrate 110 with ultraviolet light so that a plating material is deposited using electroless plating (step S222). Furthermore, step S220 further includes a step for subjecting the resin substrate 110 to electroless plating so that the second patterned layer 130 is formed in the second portion (step S224). Hereinafter, these steps will be described.

In step S222, the second portion on the surface of the resin substrate 110 is irradiated with ultraviolet light. The second portion on the surface of the resin substrate 110 is modified by the ultraviolet irradiation, so that an electroless plating layer is deposited. Here, the selective irradiation with ultraviolet light is performed so that the second portion is irradiated with ultraviolet light, and the part of a resin exposed portion of the surface of the resin substrate 110 that is other than the second portion is not irradiated with ultraviolet light.

On the other hand, in step S222, at least a part of the first portion may also be irradiated with ultraviolet light, because even if the first patterned layer 120, which is a metal layer, is irradiated with ultraviolet light, the metal layer is not modified. In this way, in step S222, it is possible to irradiate both of the second portion and at least a part of the first portion with ultraviolet light. Specifically, if the first portion and the second portion are adjacent to each other, both of the first portion and the second portion in a boundary portion between the first portion and the second portion can be irradiated with ultraviolet light. According to such a configuration, it is possible to irradiate the boundary portion between the first portion and the second portion with sufficient ultraviolet light, and thus it is easy to bring the first patterned layer 120 and the second patterned layer 130 into contact with each other, compared to a case where only the second portion is selectively irradiated with ultraviolet light. This method can be used to form the second patterned layer so that at least a part thereof is in contact with the first patterned layer.

The irradiation method and the intensity of ultraviolet light can be selected based on the description relating to step S212.

In step S224, the resin substrate 110 is subjected to electroless plating so that the second patterned layer 130 is formed in the second portion. Since, in step S222, the second portion is selectively modified, the second patterned layer 130 can selectively be provided in the second portion of the resin substrate 110 in step S224. Accordingly, in the present embodiment, the resin substrate 110 may also be dipped in an electroless plating solution in step S224.

A specific electroless plating method can be selected based on the description relating to step S214. On the other hand, in the present embodiment, the conditions of the electroless plating in step S224 are selected so that no plating material is deposited on the first patterned layer 120.

In one embodiment, the electroless plating is performed in the following manner. That is, when the resin substrate 110 to which a catalyst is added is dipped in an electroless plating solution, a reducing agent in the electroless plating solution is degraded by the catalyst, and a generated electron reduces a metal ion in the electroless plating solution. Accordingly, at a position to which the catalyst is added, a metal is deposited due to the reduction. Then, the deposited metal itself reacts as a catalyst for promoting a degradation reaction of a reducing agent, and thus the metal is further deposited.

Accordingly, in step S224, the plating conditions are selected so that the first patterned layer 120 does not react as a catalyst for promoting degradation of a reducing agent for use in electroless plating. That is, the reducing agent that is contained in the electroless plating solution used in step S224 is selected so that the first patterned layer 120 dose not promote a degradation reaction. On the other hand, the reducing agent that is contained in the electroless plating solution used in step S224 is selected so that the second patterned layer 130 promotes a degradation reaction. According to such conditions, it is possible to form the second patterned layer 130 so that no plating material is deposited on the first patterned layer 120. In order that a degradation reaction is controlled in this way, the material that is not contained in the first patterned layer 120 is contained in the second patterned layer 130.

A combination of such electroless plating methods may include an example in which the first patterned layer 120 is made of copper, and the second patterned layer 130 is made of a combination of copper and nickel. In this case, the electroless plating solution for use in forming the first patterned layer 120 may contain formalin as a reducing agent. Degradation of formalin is promoted by copper used as a catalyst. Furthermore, the electroless plating solution for use in forming the second patterned layer 130 may contain hypophosphite (for example, sodium hypophosphite) as a reducing agent. Degradation of hypophosphite is promoted by nickel used as a catalyst.

According to the present embodiment, it is possible to control the plating conditions for forming the first patterned layer 120, and the plating conditions for forming the second patterned layer 130 independently. Accordingly, it is easy both to form a first patterned layer 120 and a second patterned layer 130 that have the same thickness, and to form a first patterned layer 120 and a second patterned layer 130 that have different thicknesses.

On the other hand, the inventors of the present application have found that a binder contained in a conditioner solution may remain on the first patterned layer 120, and in this case, the second patterned layer 130 may be formed on the first patterned layer. Accordingly, in one embodiment, the conditioner treatment is omitted when the second patterned layer 130 is formed. In this case, a catalytic ion that is likely to adhere to the second portion of the resin substrate 110 without the conditioner treatment may be used. Examples of such a catalyst include a cationic complex. For example, a basic amino acid complex of palladium(II) may be used as a catalytic ion. On the other hand, in forming the first patterned layer 120, the conditioner treatment may be performed, and an anionic complex such as a hydrochloric acid palladium(II) complex may be used as a catalytic ion. Alternatively, in forming the second patterned layer 130, soft etching using acid such as sulfuric acid may be performed after the conditioner treatment, so as to remove the binder remaining on the first patterned layer 120.

Furthermore, if the conditions when the second patterned layer 130 is formed are such that a plating material is more likely to be deposited than when the first patterned layer 120 is formed, then the second patterned layer 130 may be formed at an unintended position. This may be caused because the binder contained in the conditioner solution remains on the resin substrate 110. In such a case, soft etching using acid such as sulfuric acid may be performed before the activator treatment for forming the second patterned layer 130, so as to remove the binder remaining on the resin substrate 110. Such soft etching may be performed after, for example, the first patterned layer 120 is formed.

### EMBODIMENT 2

Embodiment 1 has described a case where the first patterned layer 120 and the second patterned layer 130 are formed on the resin substrate 110. However, it is also possible to prepare a resin substrate 110 that is provided with, in a first portion on a surface thereof, a first patterned layer 120. Furthermore, a ready-made product in which a layer is formed entirely or partially on a substrate surface by plating or attaching a foil may be purchased, and the purchased product may be subjected to patterning processing using photolithography and etching, and the like to prepare a resin substrate 110 provided with the first patterned layer 120. Then, the resin substrate thus prepared may be subjected to the same processing as in step S220. That is, by irradiating a second portion on the surface of the resin substrate 110 with ultraviolet light, and subjecting the second portion to electroless plating so that a second patterned layer 130 is formed in the second portion, it is also possible to prepare a resin product 100. The resin substrate 110 that is provided with the first patterned layer 120 may be purchased and prepared. Furthermore, it is also possible to prepare a resin substrate 110 provided with a first patterned layer 120 by subjecting the resin substrate 110 to plating or patterning using photolithography and etching, for example.

According to such configuration, it is possible to easily correct, for example, a commercially available resin substrate with a patterned layer. For example, a substrate with a wiring pattern may be subjected to such processing, so that a wiring pattern is corrected.

### EMBODIMENT 3

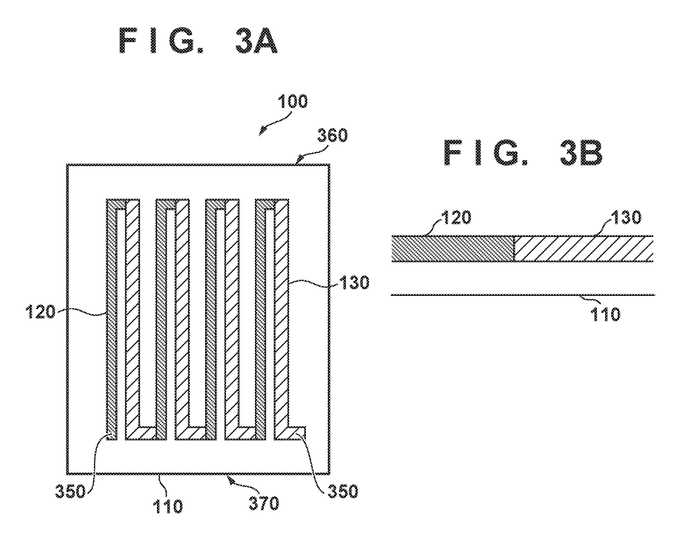

FIG. 3A shows an example of a resin product 100 according to Embodiment 3. The resin product 100 is provided with a resin substrate 110, a first patterned layer 120 of a first material, and a second patterned layer 130 of a second material, the first patterned layer 120 and the second patterned layer 130 being formed on a surface of the resin substrate 110. In one embodiment, the first patterned layer 120 and the second patterned layer 130 are provided on the same surface of the resin substrate 110. The first patterned layer 120 and the second patterned layer 130 may be in contact with each other, or may be at least partially in contact with each other. For example, the resin product 100 may be provided with a first patterned layer and a second patterned layer that are not in contact with each other, the first patterned layer and the second patterned layer being functional films having different functions.

A method for manufacturing the resin product 100 according to the present embodiment is not particularly limited. However, the manufacturing methods according to Embodiments 1 and 2 are suitable for manufacturing the resin product 100 according to Embodiment 3. In other words, according to Embodiments 1 and 2, it is possible to easily form a resin product provided with a plurality of patterned layers made of different materials. Furthermore, according to Embodiments 1 and 2, it is possible to easily form a resin product provided with fine patterned layers.

The resin product 100 shown in FIG. 3A may be used as a Seebeck element that generates electricity using a temperature difference, or a Peltier element that generates a temperature difference using electricity. In FIG. 3A, the first material of which the first patterned layer 120 is made is an electrically conductive material, and a second material of which the second patterned layer 120 is made is an electrically conductive material that is different from the first material. Furthermore, in FIG. 3A, the first patterned layer 120 and the second patterned layer 130 are in contact with each other. A temperature difference between an end portion 360 and an end portion 370 may be used to extract electricity between terminals 350. Various known combinations of such materials include combinations of chromel/alumel, iron/constantan, and copper/iron. Particularly, when copper is used as the first material, and a combination of copper and nickel (constantan) is used as the second material, an inexpensive and highly-efficient Seebeck element can be produced.

In one embodiment, as shown in FIG. 3A, the first patterned layer 120 and the second patterned layer 130 are stripe-shaped extending from the end portion 360 to the end portion 370, and the stripe-shaped portions are alternately arranged on the same surface of the resin substrate. Furthermore, one of belt-shaped layers constituting the first patterned layer 120 is connected to a belt-shaped layer that constitutes the second patterned layer 130 at an end portion on the end portion 360 side. Furthermore, this belt-shaped layer constituting the second patterned layer 130 is connected to another belt-shaped layer that constitutes the first patterned layer 120 at an end portion on the end portion 370 side. Furthermore, one of the belt-shaped layers that constitute the first patterned layer 120 is in contact with, at the end portion on the end portion 360 side, a belt-shaped layer of the second patterned layer 130 that is adjacent thereto on one side, and is in contact with, at an end portion on the end portion 370 side, a belt-shaped layer of the second patterned layer 130 that is adjacent thereto on the other side. Accordingly, in one embodiment, the first patterned layer 120 and the second patterned layer 130 are connected in series in an alternating manner. In other words, the first patterned layer 120 and the second patterned layer 130 are connected to each other in an alternating manner to form one patterned layer as a whole. In FIG. 3A, a connection portion of the first patterned layer 120 and the second patterned layer 130 is provided in the vicinity of the end portion 360 or the vicinity of the end portion 370. According to such a configuration, it is structurally easy to provide a temperature difference between the end portion 360 and the end portion 370.

The shapes of the first patterned layer 120 and the second patterned layer 130 are not particularly limited. Furthermore, at least either one of the first patterned layer 120 and the second patterned layer 130 may include two or more films. For example, the first patterned layer 120 and the second patterned layer 130 may be belt-shaped or stripe-shaped.

In the present embodiment, the first patterned layer 120 and the second patterned layer 130 are configured to be at least partially in contact with each other but not to overlap each other. FIG. 3B shows a connection portion of the first patterned layer 120 and the second patterned layer 130. Accordingly, the first patterned layer 120 and the second patterned layer 130 are formed directly on the resin substrate 110, and thus patterned layers are in contact with each other but do not overlap each other, making it possible to suppress the thickness of the resin product 100. In one embodiment, the first patterned layer 120 and the second patterned layer 130 do not overlap each other on the resin substrate 110 but are adjacent and in contact with each other along the surface of the resin substrate 110 while being electrically connected to each other.

Manufacturing methods according to Embodiments 1 and 2 are suitable for manufacturing the resin product 100 as shown in FIGS. 3A and 3B. In other words, the methods described with reference to Embodiments 1 and 2 can be used so that the first patterned layer 120 and the second patterned layer 130 do not overlap each other, and at the same time the first patterned layer 120 and the second patterned layer 130 are in contact with each other.

Furthermore, in the present embodiment, the first patterned layer 120 and the second patterned layer 130 have the same thickness. On the other hand, the first patterned layer 120 and the second patterned layer 130 may have different thicknesses. In other words, the thickness of the patterned layer may vary according to the use. For example, it is also possible to make a patterned layer that configures a power supply circuit thicker so that it has a low resistance, and make a patterned layer that configures a signal circuit thinner so that it has high integration degree. As described above, the manufacturing methods according to Embodiments 1 and 2 are suitable for controlling the thickness of the patterned layer, because the first patterned layer 120 and the second patterned layer 130 can be provided in separate steps.

### EMBODIMENT 4

The following will describe a resin product 500 according to Embodiment 4. Similar to the resin product 100 according to Embodiment 3, the resin product 500 is provided with a resin substrate 110 that is provided with, on a surface thereof, a first patterned layer 120 of a first material, and a second patterned layer 130 of a second material. The first material of which the first patterned layer 120 is made is an electrically conductive material, and the second material of which the second patterned layer 120 is made is an electrically conductive material that is different from the first material. Also, the first patterned layer 120 and the second patterned layer 130 are in contact with each other. The first patterned layer 120 and the second patterned layer 130 can be provided so as to be connected to each other continuously and in an alternating manner while being in contact with each other at end portions thereof.

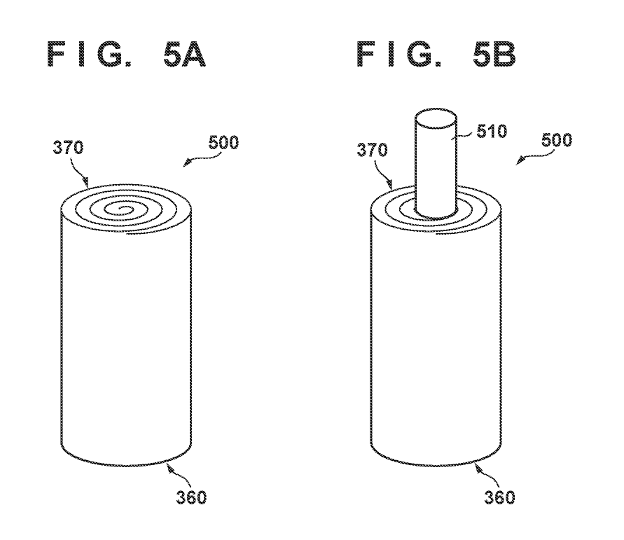

The resin product 500 has such a structure that the resin substrate 110 provided with the first patterned layer 120 and the second patterned layer 130 is stacked. The resin product 500 may have a structure such that one resin substrate is rolled as shown in FIG. 5A, or may have a structure in which a separate resin substrate 110 is stacked thereon. For example, as a result of the resin product 100 shown in FIG. 3A being rolled, or a plurality of resin products 100 being stacked on each other, the resin product 500 having a stacked structure can be produced.

In one embodiment, the resin product 500 has a shape such that the resin substrate 110 is rolled. An end of the rolled resin product 500 corresponds to the end portion 360, and the other end thereof corresponds to the end portion 370. Since connection portions of the first patterned layer 120 and the second patterned layer 130 are provided in the vicinities of the end portion 360 and the end portion 370, it is possible to gain electricity between the terminals 350 by providing a temperature difference between the end portion 360 and the end portion 370. Accordingly, the resin product 500 can serve as a Seebeck element or a Peltier element, and the resin product 500 can be used to produce a thermocouple. If the rolled resin product 500 is used to obtain an electromotive force, then a range to be heated or cooled can be set to be smaller than in a case where the non-rolled resin product 100 shown in FIG. 3A is used, and thus it is possible to efficiently obtain an electromotive force.

As shown in FIG. 5B, the rolled resin product 500 may have a heat pipe 510 inside thereof. The heat pipe 510 protrudes outward from one end portion 370, and does not reach the other end portion 360. Such a configuration can promote cooling of the end portion 370, and thus it is possible to efficiently obtain an electromotive force. Examples of the material of the heat pipe 510 include a high thermal conductive material such as copper. In this case, an insulating material may be provided around the heat pipe 510, or the positions of the first patterned layer 120 and the second patterned layer 130 may be adjusted, so as to prevent a short circuit from occurring due to the heat pipe 510.

In another embodiment, the resin product 500 may have a shape such that the resin substrate 110 is folded. In this case, the first patterned layer 120 and the second patterned layer 130 may appropriately be determined so as to prevent a wiring line from being short-circuited after the resin substrate 110 is folded. Furthermore, an insulating material layer may also be provided in the folded substrate so as to prevent a short circuit.

Furthermore, as described above, the present invention includes a method for providing layers made of a plurality of different materials on a resin product. That is, present invention is not limited to a method for forming, on the same surface of a substrate, layers using two types of materials. For example, it is possible to form patterned layers of two or more types of materials on the same surface of a resin substrate, by configuring such that a layer that is formed first does not contain a catalyst component for promoting deposition of a layer that is formed later.

### Working Example 1

A sheet-like cycloolefin polymer (“ZEONOR film ZF-16” of ZEON Corporation, thickness of 100 μm) was used as a resin substrate 410. This resin substrate has a glass-transition temperature of 160° C.

### First Formation Step

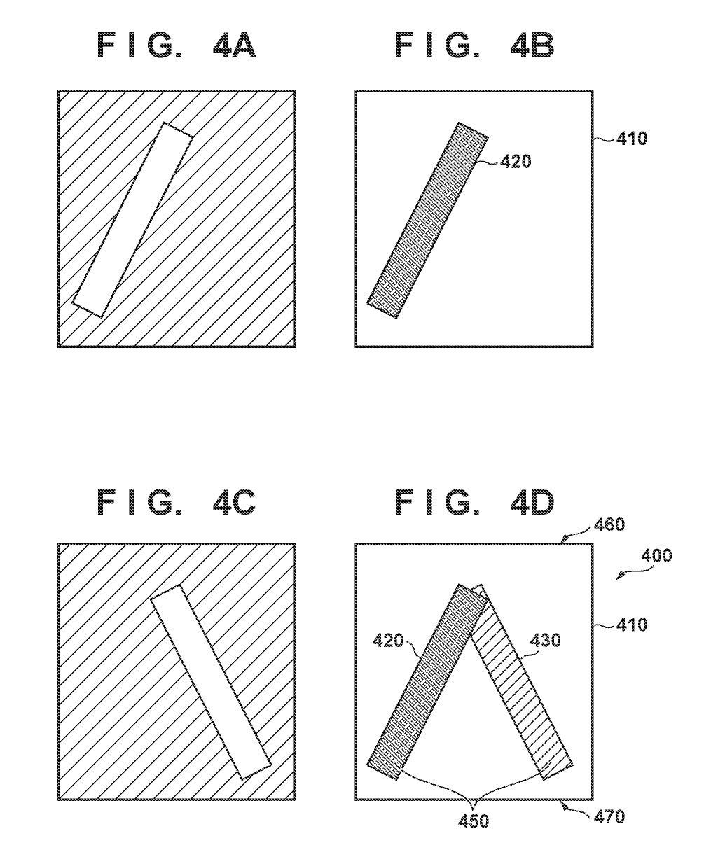

First, a photomask was set on the resin substrate 410. This photomask has an opening that is shown in FIG. 4A, and the shape of the opening corresponds to a first patterned layer 420. The hatched portion of FIG. 4A indicates a portion through which no ultraviolet light is transmitted.

Then, irradiation with ultraviolet light was performed via an ultraviolet light mask. The ultraviolet lamp (low-pressure mercury lamp) that was used in this working example has the following detailed specifications.

Low-pressure mercury lamp: “UV-300” of Samco Incorporated (main wavelengths of 185 nm and 254 nm)

Illumination intensities at an irradiation distance of 3.5 cm: 5.40 mW/cm² (254 nm) and 1.35 mW/cm² (185 nm)

Specifically, the above-described ultraviolet lamp was used to irradiate the resin substrate 410 with ultraviolet light of 1.35 mW/cm² (185 nm) for 20 minutes with the resin substrate 410 distanced by 3.5 cm away from the ultraviolet lamp. In this case, the integrated exposure amount is obtained as follows: 1.35 mW/cm²×1200 second=1620 mJ/cm².

Then, Cu—Ni plating solution set “AISL” of JCU Corporation was used to subject a resin product 400 to electroless plating. Specific processing conditions are as follows. Note that Cu plating solution “PB507F” of JCU Corporation was used as an electroless plating solution. Water washing was performed after the end of each step. Note that the activator liquid “AISL” contains hydrochloric acid palladium (II).

TABLE 1

| | TEMPERATURE | TIME |
|---|---|---|
| ALKALI TREATMENT (AISL) | 50° C. | 2 MIN |
| CONDITIONER TREATMENT (AISL) | 50° C. | 5 MIN |
| ACTIVATOR TREATMENT | 50° C. | 5 MIN |
| (CATALYTIC ION ADDITION) (AISL) | | |
| ACCELERATOR TREATMENT | 40° C. | 2 MIN |
| (CATALYST DEPOSITION) (AISL) | | |
| ELECTROLESS Cu PLATING (PB507F) | 60° C. | 30 MIN |

When electroless plating was performed in accordance with the steps shown in Table 1, the first patterned layer 420 was formed in the portion that was irradiated with the ultraviolet light. The resin product obtained using the plating is shown in FIG. 4B.

### Second Formation Step

Then, a new photomask was set on the resin substrate 410. This photomask has an opening that is shown in FIG. 4C, and the shape of the opening substantially corresponds to a second patterned layer 430, but a part of the first patterned layer 420 is also exposed from the opening. The hatched portion of FIG. 4C indicates a portion through which no ultraviolet light is transmitted.

Then, irradiation with ultraviolet light was performed under the same conditions as those in the first formation step, except for the irradiation with ultraviolet light lasting for 30 minutes. Furthermore, Cu—Ni plating solution sets “AISL” and “ELFSEED” of JCU Corporation were used to subject the resin product 400 to electroless plating. Specific processing conditions are as follows. Note that, as an electroless plating solution, Cu—Ni plating solution “PB570” of JCU Corporation was used with the amount of nickel doubled. Water washing was performed after the end of each step. Note that the activator liquid “ELFSEED” contains a palladium (II) basic amino acid complex.

TABLE 2

| | TEMPERATURE | TIME |
|---|---|---|
| ALKALI TREATMENT (AISL) | 50° C. | 2 MIN |
| ACTIVATOR TREATMENT (CATALYTIC | 50° C. | 5 MIN |
| ION ADDITION) (ELFSEED) | | |
| ACCELERATOR TREATMENT | 40° C. | 4 MIN |
| (CATALYST DEPOSITION) (ELFSEED) | | |
| ELECTROLESS Cu—Ni PLATING | 60° C. | 7 MIN |
| (PB570) | | |

When electroless plating was performed in accordance with the steps shown in Table 2, the second patterned layer 430 was formed in the portion that was irradiated with the ultraviolet light, and in which the first patterned layer 420 was not formed. The resin product 400 obtained using plating is shown in FIG. 4D.

### Evaluation

Potential differences between terminals 450 were measured in a state in which the obtained resin product 400 was heated on the end portion 460 side with a hot plate but not on the end portion 470 side. Relationships between the temperature on the end portion 460 side and the potential difference are shown below.
23° C.-0.02 mV
40° C.-0.22 mV
51° C.-0.32 mV
68° C.-0.48 mV
89° C.-0.69 mV
93° C.-0.72 mV
101° C.-0.79 mV

Accordingly, it was observed that the resin product 400 is available as a Seebeck element, and the first patterned layer 420 and the second patterned layer 430 are electrically connected to each other.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2016-195991, filed Oct. 3, 2016, which is hereby incorporated by reference herein in its entirety.

1. A method of manufacturing a resin product, comprising:
preparing a resin substrate that is provided with, in a first portion on a surface of the resin substrate, a first patterned layer of a first material; and
forming a second patterned layer of a second material in a second portion on the surface of the resin substrate, by irradiating the second portion with ultraviolet light and then subjecting the second portion to electroless plating.

2. The method according to claim 1,
wherein the forming comprises selecting a plating condition so that no plating material is deposited on the first patterned layer.

3. The method according to claim 1,
wherein the forming comprises selecting a plating condition so that the first material does not act as a catalyst for promoting degradation of a reducing agent for use in the electroless plating.

4. The method according to claim 1,
wherein the forming comprises forming the second patterned layer so that the second patterned layer is at least partially in contact with the first patterned layer.

5. The method according to claim 1,
wherein the forming comprises irradiating both of the second portion and at least a part of the first portion with ultraviolet light.

6. The method according to claim 1,
wherein the first material is copper, and the second material is a combination of copper and nickel.

7. The method according to claim 1,
wherein the preparing comprises forming the first patterned layer in the first portion on the surface of the resin substrate, by irradiating the first portion with ultraviolet light and then subjecting the first portion to electroless plating.

8. The method according to claim 1,
wherein patterned layers of two or more types of materials are formed on the same surface of the resin substrate, by configuring such that a layer that is formed first does not contain a catalyst component for promoting deposition of a layer that is formed later.

9. A resin product that is manufactured by a method comprising:
preparing a resin substrate that is provided with, in a first portion on a surface of the resin substrate, a first patterned layer of a first material; and
forming a second patterned layer of a second material in a second portion on the surface of the resin substrate, by irradiating the second portion with ultraviolet light and then subjecting the second portion to electroless plating.

10. A resin product comprising:
a resin substrate;
a first patterned layer of a first material that is provided on a surface of the resin substrate; and
a second patterned layer of a second material that is provided on the surface of the resin substrate.

11. The resin product according to claim 10,
wherein the first patterned layer and the second patterned layer do not overlap each other.

12. The resin product according to claim 10,
wherein the first patterned layer and the second patterned layer are at least partially in contact with each other.

13. The resin product according to claim 10,
wherein the resin substrate that is provided with the first patterned layer and the second patterned layer is stacked.

14. The resin product according to claim 10,
wherein the resin substrate that is provided with the first patterned layer and the second patterned layer is rolled.

15. The resin product according to claim 10,
wherein the resin product is a Seebeck element or a Peltier element.
